(19) United States
(12) Patent Application Publication
(10) Pub. No.: US 2011/0044475 A1
(43) Pub. Date: Feb. 24, 2011

(54) AUDIO ADAPTER, EARPHONE AND SPEAKER BOX

(75) Inventor: Bill Yang, Taipei City (TW)

Correspondence Address: J C PATENTS, 4 VENTURE, SUITE 250, IRVINE, CA, 92618, US

(73) Assignee: COTRON CORPORATION, Taipei City (TW)

(21) Appl. No.: 12/561,892

(22) Filed: Sep. 17, 2009

(30) Foreign Application Priority Data
Aug. 20, 2009 (TW) 98128144

(51) Int. Cl. H03G 3/00; H04R 1/00; H03G 5/02

(52) U.S. Cl. 381/109; 381/380; 333/28 T

(57) ABSTRACT

An audio adapter including a first connector, a second connector, a manually adjustable passive audio adjusting unit, and a signal line is provided. The signal line sequentially connects the first connector, the manually adjustable passive audio adjusting unit, and the second connector. An earphone and a speaker box using the same manually adjustable passive audio adjusting unit are also provided.

### CROSS-REFERENCE TO RELATED APPLICATION

This application claims the priority benefit of Taiwan application serial no. 98128144, filed on Aug. 20, 2009. The entirety of the above-mentioned patent application is hereby incorporated by reference herein and made a part of this specification.

### BACKGROUND OF THE INVENTION

1. Field of the Invention

The present invention generally relates to an audio adapter, an earphone, and a speaker box, and more particularly, to an audio adapter, an earphone, and a speaker box with adjustable audio frequency.

2. Description of Related Art

Video/audio enjoyment has become one of the most indispensable parts of our daily life. However, since everybody has different taste in music, sound equipments with the same specification cannot meet the requirements of all people. Most existing earphones and speaker boxes provide a fixed frequency response curve, and an electronic equalizer has to be adopted to change the frequency response within the high-frequency range or the low-frequency range. An active electronic equalizer consumes electric power and is inconvenient to use even though it can be used to change the frequency response curve of an earphone or a speaker box.

According to U.S. Patent application No. US20070098202, a high frequency boost function is started by using a switch, so as to improve the sensitivity to high-frequency signals and reduce the sensitivity to low-frequency signals. However, the present technique only allows the filtering function to be simply turned on and off but not finely adjusted to meet the requirements of different users.

According to U.S. Pat. No. 7,088,833, signals to different speakers of a speaker box are respectively filtered by using an all pass filter and a low pass filter. However, the present technique does not allow the all pass filter and the low pass filter to be adjusted so that it still cannot meet the requirements of different users.

### SUMMARY OF THE INVENTION

Accordingly, the present invention is directed to an audio adapter which does not consume electric power and allows the audio frequency to be manually adjusted.

The present invention is also directed to an earphone which does not consume electric power and allows the audio frequency to be manually adjusted.

The present invention is further directed to a speaker box which does not consume electric power and allows the audio frequency to be manually adjusted.

The present invention provides an audio adapter including a first connector, a second connector, a first manually adjustable passive audio adjusting unit, and a signal line. The signal line sequentially connects the first connector, the first manually adjustable passive audio adjusting unit, and the second connector.

In an embodiment of the audio adapter according to the present invention, an audio adjustment range of the first manually adjustable passive audio adjusting unit is smaller than or equal to 300 Hz. Besides, the audio adapter may further include a second manually adjustable passive audio adjusting unit. The second manually adjustable passive audio adjusting unit is connected between the first connector and the second connector by the signal line, and an audio adjustment range of the second manually adjustable passive audio adjusting unit is greater than or equal to 3000 Hz.

In an embodiment of the audio adapter according to the present invention, the first manually adjustable passive audio adjusting unit may include a manually adjustable resistor, a first capacitor, and a second capacitor. The first capacitor is connected with the manually adjustable resistor in series, and the second capacitor is connected with the manually adjustable resistor and the first capacitor in parallel.

In an embodiment of the audio adapter according to the present invention, the audio adjustment range of the first manually adjustable passive audio adjusting unit is greater than or equal to 3000 Hz.

In an embodiment of the audio adapter according to the present invention, the first manually adjustable passive audio adjusting unit includes a manually adjustable resistor and a capacitor. The capacitor is connected with the manually adjustable resistor in series. One of the manually adjustable resistor and the capacitor is grounded, and the other one of the manually adjustable resistor and the capacitor is connected to the signal line.

The present invention provides an earphone including a connector, a first earphone unit, a second earphone unit, a first manually adjustable passive audio adjusting unit, and a signal line. The signal line sequentially connects the connector, the first manually adjustable passive audio adjusting unit, and the first earphone unit and sequentially connects the connector, the first manually adjustable passive audio adjusting unit, and the second earphone unit.

In an embodiment of the earphone according to the present invention, an audio adjustment range of the first manually adjustable passive audio adjusting unit is smaller than or equal to 300 Hz. Besides, the earphone may further include a second manually adjustable passive audio adjusting unit. The second manually adjustable passive audio adjusting unit is connected between the connector and the first earphone unit by the signal line, and the second manually adjustable passive audio adjusting unit is also connected between the connector and the second earphone unit by the signal line. An audio adjustment range of the second manually adjustable passive audio adjusting unit is greater than or equal to 3000 Hz.

In an embodiment of the earphone according to the present invention, the first manually adjustable passive audio adjusting unit includes a manually adjustable resistor, a first capacitor, and a second capacitor. The first capacitor is connected with the manually adjustable resistor in series. The second capacitor is connected with the manually adjustable resistor and the first capacitor in parallel.

In an embodiment of the earphone according to the present invention, the audio adjustment range of the first manually adjustable passive audio adjusting unit is greater than or equal to 3000 Hz.

In an embodiment of the earphone according to the present invention, the first manually adjustable passive audio adjusting unit includes a manually adjustable resistor and a capacitor. The capacitor is connected with the manually adjustable resistor in series. One of the manually adjustable resistor and the capacitor is grounded, and the other one of the manually adjustable resistor and the capacitor is connected to the signal line.

The present invention provides another earphone including a connector, a first earphone unit, a second earphone unit, a first manually adjustable passive audio adjusting unit, a second manually adjustable passive audio adjusting unit, and a signal line. The signal line sequentially connects the connector, the first manually adjustable passive audio adjusting unit, and the first earphone unit and sequentially connects the connector, the second manually adjustable passive audio adjusting unit, and the second earphone unit.

In an embodiment of the earphone according to the present invention, an audio adjustment range of the first manually adjustable passive audio adjusting unit is smaller than or equal to 300 Hz. Besides, the earphone may further include a third manually adjustable passive audio adjusting unit. The third manually adjustable passive audio adjusting unit is connected between the connector and the first earphone unit by the signal line, and an audio adjustment range of the third manually adjustable passive audio adjusting unit is greater than or equal to 3000 Hz.

In an embodiment of the earphone according to the present invention, the first manually adjustable passive audio adjusting unit includes a manually adjustable resistor, a first capacitor, and a second capacitor. The first capacitor is connected with the manually adjustable resistor in series. The second capacitor is connected with the manually adjustable resistor and the first capacitor in parallel.

In an embodiment of the earphone according to the present invention, the audio adjustment range of the first manually adjustable passive audio adjusting unit is greater than or equal to 3000 Hz.

Besides, the first manually adjustable passive audio adjusting unit includes a manually adjustable resistor and a capacitor. The capacitor is connected with the manually adjustable resistor in series. One of the manually adjustable resistor and the capacitor is grounded, and the other one of the manually adjustable resistor and the capacitor is connected to the signal line.

In an embodiment of the earphone according to the present invention, an audio adjustment range of the second manually adjustable passive audio adjusting unit is smaller than or equal to 300 Hz. Besides, the earphone further includes a third manually adjustable passive audio adjusting unit. The third manually adjustable passive audio adjusting unit is connected between the connector and the second earphone unit by the signal line, and an audio adjustment range of the third manually adjustable passive audio adjusting unit is greater than or equal to 3000 Hz.

In an embodiment of the earphone according to the present invention, the second manually adjustable passive audio adjusting unit includes a manually adjustable resistor, a first capacitor, and a second capacitor. The first capacitor is connected with the manually adjustable resistor in series. The second capacitor is connected with the manually adjustable resistor and the first capacitor in parallel.

In an embodiment of the earphone according to the present invention, the audio adjustment range of the first manually adjustable passive audio adjusting unit is greater than or equal to 3000 Hz.

In an embodiment of the earphone according to the present invention, the first manually adjustable passive audio adjusting unit includes a manually adjustable resistor and a capacitor. The capacitor is connected with the manually adjustable resistor in series. One of the manually adjustable resistor and the capacitor is grounded, and the other one of the manually adjustable resistor and the capacitor is connected to the signal line.

In an embodiment of the earphone according to the present invention, the audio adjustment range of the second manually adjustable passive audio adjusting unit is smaller than or equal to 300 Hz. Besides, the earphone further includes a third manually adjustable passive audio adjusting unit. The third manually adjustable passive audio adjusting unit is connected between the connector and the second earphone unit by the signal line, and an audio adjustment range of the third manually adjustable passive audio adjusting unit is greater than or equal to 3000 Hz.

In an embodiment of the earphone according to the present invention, the second manually adjustable passive audio adjusting unit includes a manually adjustable resistor, a first capacitor, and a second capacitor. The first capacitor is connected with the manually adjustable resistor in series. The second capacitor is connected with the manually adjustable resistor and the first capacitor in parallel.

In an embodiment of the earphone according to the present invention, the audio adjustment range of the second manually adjustable passive audio adjusting unit is greater than or equal to 3000 Hz.

In an embodiment of the earphone according to the present invention, the second manually adjustable passive audio adjusting unit includes a manually adjustable resistor and a capacitor. The capacitor is connected with the manually adjustable resistor in series. One of the manually adjustable resistor and the capacitor is grounded, and the other one of the manually adjustable resistor and the capacitor is connected to the signal line.

The present invention provides a speaker box including a connector, a speaker box body, a first manually adjustable passive audio adjusting unit, and a signal line. The signal line sequentially connects the connector, the first manually adjustable passive audio adjusting unit, and the speaker box body.

In an embodiment of the speaker box according to the present invention, an audio adjustment range of the first manually adjustable passive audio adjusting unit is smaller than or equal to 300 Hz. Besides, the speaker box may further include a second manually adjustable passive audio adjusting unit. The second manually adjustable passive audio adjusting unit is connected between the connector and the speaker box body by the signal line, and an audio adjustment range of the second manually adjustable passive audio adjusting unit is greater than or equal to 3000 Hz.

In an embodiment of the speaker box according to the present invention, the first manually adjustable passive audio adjusting unit includes a manually adjustable resistor, a first capacitor, and a second capacitor. The first capacitor is connected with the manually adjustable resistor in series. The second capacitor is connected with the manually adjustable resistor and the first capacitor in parallel.

In an embodiment of the speaker box according to the present invention, the audio adjustment range of the first manually adjustable passive audio adjusting unit is greater than or equal to 3000 Hz.

In an embodiment of the speaker box according to the present invention, the first manually adjustable passive audio adjusting unit includes a manually adjustable resistor and a capacitor. The capacitor is connected with the manually adjustable resistor in series. One of the manually adjustable resistor and the capacitor is grounded, and the other one of the manually adjustable resistor and the capacitor is connected to the signal line.

As described above, in an audio adapter, an earphone, and a speaker box provided by the present invention, the manually adjustable passive audio adjusting units allow the audio frequency to be manually adjusted without consuming any electric power and accordingly make the adjustment of the audio frequency very convenient.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram of an earphone according to an embodiment of the present invention.

FIG. 2 is a diagram of an earphone according to another embodiment of the present invention.

FIG. 3 illustrates a frequency response curve of the earphone in FIG. 1.

FIG. 4, FIG. 5A, FIG. 6, and FIG. 7 are diagrams of earphones according to another four embodiments of the present invention.

FIG. 5B and FIG. 5C are circuit diagrams of two manually adjustable passive audio adjusting units of the earphone in FIG. 5A.

FIGS. 8˜10 are diagrams of audio adapters according to three embodiments of the present invention.

FIGS. 11˜13 are diagrams of speaker boxes according to three embodiments of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

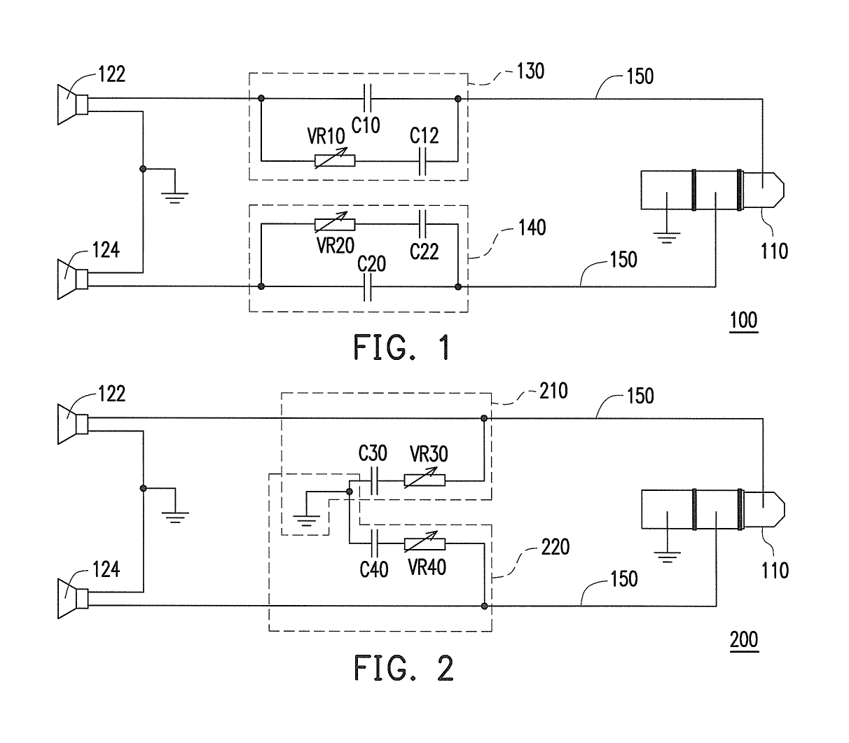

FIG. 1 is a diagram of an earphone according to an embodiment of the present invention. Referring to FIG. 1, in the present embodiment, the earphone 100 includes a connector 110, an earphone unit 122, an earphone unit 124, a manually adjustable passive audio adjusting unit 130, a manually adjustable passive audio adjusting unit 140, and a signal line 150. The signal line 150 sequentially connects the connector 110, the manually adjustable passive audio adjusting unit 130, and the earphone unit 122 and sequentially connects the connector 110, the manually adjustable passive audio adjusting unit 140, and the earphone unit 124. Because audio signals received by the connector 110 first pass through the manually adjustable passive audio adjusting unit 130 before they reach the earphone unit 122 through the signal line 150, a user can manually operate the manually adjustable passive audio adjusting unit 130 to adjust the frequency distribution of the audio signals input into the earphone unit 122 according to the user's personal preference. Accordingly, the frequency response curve output by the earphone unit 122 can be changed and it is not needed to supply electric power to the manually adjustable passive audio adjusting unit 130. In addition, the manually adjustable passive audio adjusting unit 130 may be adjusted in a stepless or a multistep pattern. Similarly, the user can manually operate the manually adjustable passive audio adjusting unit 140 to adjust the frequency distribution of audio signals input into the earphone unit 124 according to the user's personal preference.

In the present embodiment, the manually adjustable passive audio adjusting unit 130 includes a manually adjustable resistor VR10, a capacitor C10, and a capacitor C12. The capacitor C12 is connected with the manually adjustable resistor VR10 in series. The capacitor C10 is connected with the manually adjustable resistor VR10 and the capacitor C12 in parallel. Similarly, in the present embodiment, the manually adjustable passive audio adjusting unit 140 includes a manually adjustable resistor VR20, a capacitor C20, and a capacitor C22. The capacitor C22 is connected with the manually adjustable resistor VR20 in series. The capacitor C20 is connected with the manually adjustable resistor VR20 and the capacitor C22 in parallel. Additionally, in the present embodiment, the audio adjustment range of the manually adjustable passive audio adjusting units 130 and 140 is about smaller than or equal to 300 Hz. However, the present invention is not limited thereto.

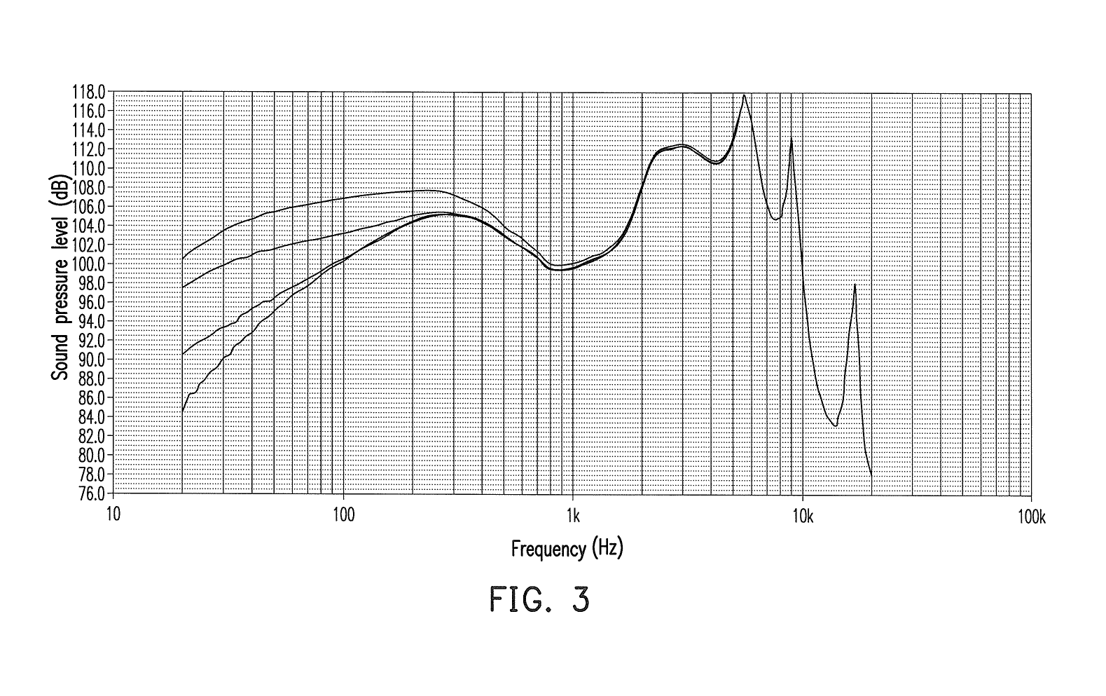

FIG. 2 is a diagram of an earphone according to another embodiment of the present invention. Referring to FIG. 2, the earphone 200 in the present embodiment is similar to the earphone 100 illustrated in FIG. 1, and only the difference between the two will be described herein. In the present embodiment, a manually adjustable passive audio adjusting unit 210 of the earphone 200 includes a manually adjustable resistor VR30 and a capacitor C30. The capacitor C30 is connected with the manually adjustable resistor VR30 in series. In the present embodiment, the capacitor C30 is grounded, and the manually adjustable resistor VR30 is connected to the signal line 150. However, it may also be that the manually adjustable resistor VR30 is grounded while the capacitor C30 is connected to the signal line 150. Similarly, a manually adjustable passive audio adjusting unit 220 in the present embodiment includes a manually adjustable resistor VR40 and a capacitor C40. The capacitor C40 is connected with the manually adjustable resistor VR40 in series. In the present embodiment, the capacitor C40 is grounded, and the manually adjustable resistor VR40 is connected to the signal line 150. However, it may also be that the manually adjustable resistor VR40 is grounded while the capacitor C40 is connected to the signal line 150. Additionally, in the present embodiment, the audio adjustment range of the manually adjustable passive audio adjusting units 210 and 220 is about greater than or equal to 3000 Hz. However, the present invention is not limited thereto.

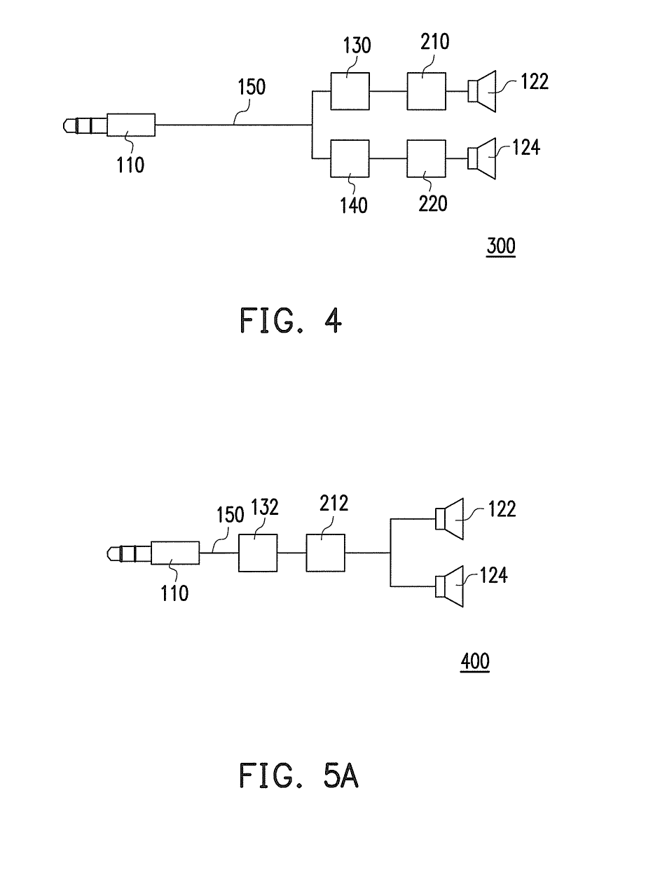

FIG. 3 illustrates the frequency response curve of the earphone in FIG. 1. Referring to FIG. 1 and FIG. 3, the four curves in FIG. 3 are respectively the frequency response curves output by the earphone unit 122 when the manually adjustable passive audio adjusting unit 130 is adjusted into four different statuses. As shown in FIG. 3, the frequency response curve output by the earphone unit 122 is actually changed by manually operating the manually adjustable passive audio adjusting unit 130.

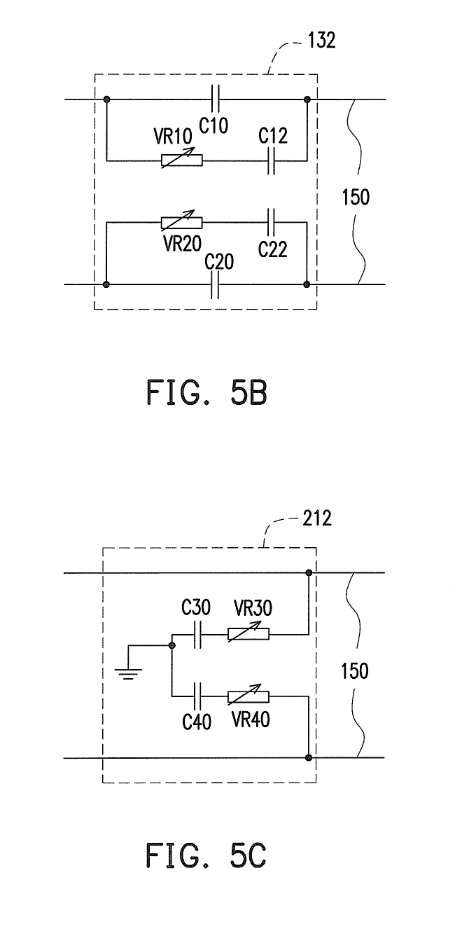

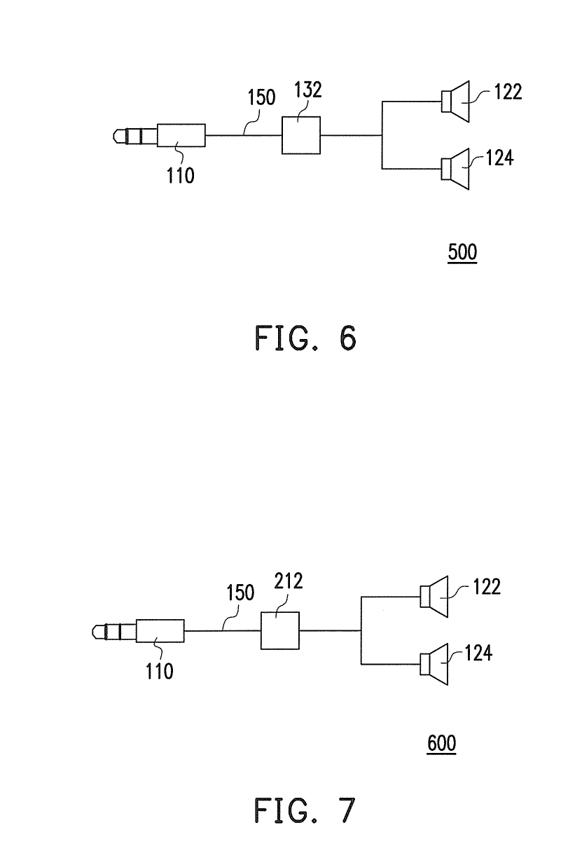

FIG. 4, FIG. 5A, FIG. 6, and FIG. 7 are diagrams of earphones according to another four embodiments of the present invention. The earphone illustrated in FIG. 4 is similar to those illustrated in FIG. 1 and FIG. 2, and only the differences are described herein. The earphone 300 in FIG. 4 has all of the manually adjustable passive audio adjusting units 130, 140, 210, and 220 such that the high-frequency parts and the low-frequency parts of the frequency response curves output by the earphone units 122 and 124 can be respectively adjusted.

FIG. 5B and FIG. 5C are circuit diagrams of two manually adjustable passive audio adjusting units of the earphone illustrated in FIG. 5A. The earphone in FIG. 5A is similar to the earphone in FIG. 4 and only the difference between the two will be described herein. The earphone 400 in FIG. 5 has both the manually adjustable passive audio adjusting units 132 and 212, and the low-frequency parts or the high-frequency parts of the frequency response curves output by the earphone units 122 and 124 can be adjusted by adjusting the manually adjustable passive audio adjusting unit 132 or 212. To be specific, the manually adjustable passive audio adjusting unit 132 includes the manually adjustable passive audio adjusting units 130 and 140 in FIG. 1. However, the manually adjustable resistors VR10 and VR20 in the manually adjustable passive audio adjusting units 130 and 140 in FIG. 1 are to be respectively adjusted by the user. Thus, the earphone 300 in FIG. 4 allows the user to adjust the resistances of the manually adjustable resistors VR10 and VR20 into different values so that the earphone units 122 and 124 can output frequency response curves having different low-frequency ranges. The manually adjustable resistors VR10 and VR20 illustrated in FIG. 5B share the same resistance adjustment mechanism. Accordingly, any adjustment done by the user changes the resistances of both the manually adjustable resistors VR10 and VR20 in FIG. 5B, so that the earphone units 122 and 124 in FIG. 5A can output frequency response curves having similar low-frequency parts. Similarly, the manually adjustable resistors VR30 and VR40 illustrated in FIG. 5C share the same resistance adjustment mechanism. Accordingly, any adjustment done by the user changes the resistances of both the manually adjustable resistors VR30 and VR40 in FIG. 5C, so that the earphone units 122 and 124 in FIG. 5A can output frequency response curves having similar high-frequency parts.

The earphones illustrated in FIG. 6 and FIG. 7 are similar to the earphone illustrated in FIG. 5A, and only the differences will be described herein. The earphone 500 in FIG. 6 has a manually adjustable passive audio adjusting unit 132, and the low-frequency parts of the frequency response curves output by the earphone units 122 and 124 can be adjusted at the same time by adjusting the manually adjustable passive audio adjusting unit 132. The earphone 600 in FIG. 7 has a manually adjustable passive audio adjusting unit 212, and the high-frequency parts of the frequency response curves output by the earphone units 122 and 124 can be adjusted at the same time by adjusting the manually adjustable passive audio adjusting unit 212.

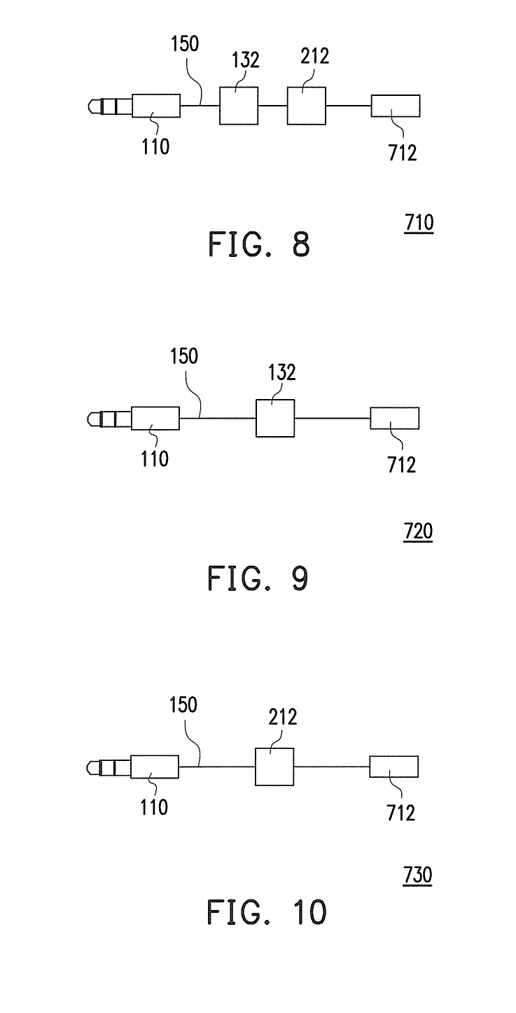

FIGS. 8˜10 are diagrams of audio adapters according to three embodiments of the present invention. Referring to FIG. 8, in the present embodiment, the audio adapter 710 includes a connector 110, a connector 712, a manually adjustable passive audio adjusting unit 132, a manually adjustable passive audio adjusting unit 212, and a signal line 150. The connector 110, the manually adjustable passive audio adjusting unit 132, the manually adjustable passive audio adjusting unit 212, and the signal line 150 are all the same as those elements having the same reference numerals in FIG. 5A. After connecting the audio adapter 710 to an audio device (not shown) and a speaker (not shown), a user can manually operate the manually adjustable passive audio adjusting units 132 and 212 according to the user's personal preference so as to adjust the frequency distribution of audio signals input into the speaker. Accordingly, the high-frequency part and the low-frequency part of the frequency response curve output by the speaker can be changed, and it is not needed to supply electric power to the manually adjustable passive audio adjusting units 132 and 212. The audio adapter 720 in FIG. 9 has only the manually adjustable passive audio adjusting unit 132 for adjusting the low-frequency part of the frequency response curve output by the speaker. The audio adapter 730 in FIG. 10 has only the manually adjustable passive audio adjusting unit 212 for adjusting the high-frequency part of the frequency response curve output by the speaker.

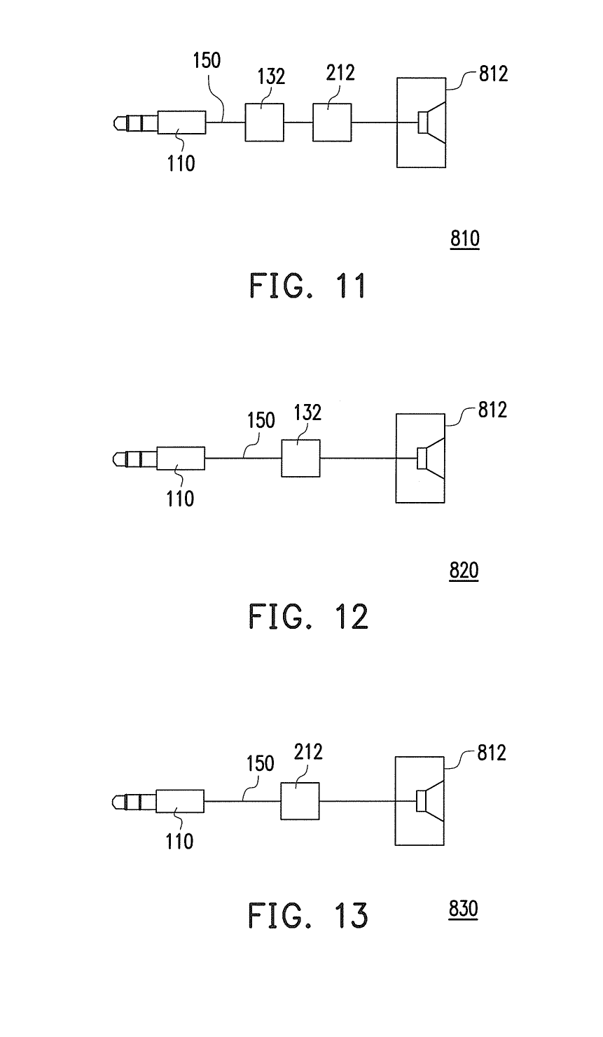

FIGS. 11˜13 are diagrams of speaker boxes according to three embodiments of the present invention. Referring to FIG. 11, in the present embodiment, the speaker box 810 includes a connector 110, a speaker box body 812, a manually adjustable passive audio adjusting unit 132, a manually adjustable passive audio adjusting unit 212, and a signal line 150. The connector 110, the manually adjustable passive audio adjusting unit 132, the manually adjustable passive audio adjusting unit 212, and the signal line 150 are all the same as those elements having the same reference numerals in FIG. 5A. After connecting the speaker box 810 to an audio device (not shown), a user can manually operate the manually adjustable passive audio adjusting units 132 and 212 according to the user's personal preference, so as to adjust the frequency distribution of audio signals input into the speaker box body 812. Accordingly, the high-frequency part and the low-frequency part of the frequency response curve output by the speaker box body 812 can be changed, and it is not needed to supply electric power to the manually adjustable passive audio adjusting units 132 and 212. The speaker box 820 in FIG. 12 has only the manually adjustable passive audio adjusting unit 132 for adjusting the low-frequency part of the frequency response curve output by the speaker box body 812. The speaker box 830 in FIG. 13 has only the manually adjustable passive audio adjusting unit 212 for adjusting the high-frequency part of the frequency response curve output by the speaker box body 812.

As described above, in an audio adapter, an earphone, and a speaker box provided by the present invention, a user can manually adjust manually adjustable passive audio adjusting units in a stepless or multistep pattern, so as to adjust the frequency distribution of audio signals, and it is not needed to supply electric power to the manually adjustable passive audio adjusting units. Thereby, the technique provided by the present invention is environment-friendly and convenient to use.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An audio adapter, comprising:
a first connector;
a second connector;
a first manually adjustable passive audio adjusting unit; and
a signal line, sequentially connected the first connector, the first manually adjustable passive audio adjusting unit, and the second connector.

2. The audio adapter according to claim 1, wherein an audio adjustment range of the first manually adjustable passive audio adjusting unit is smaller than or equal to 300 Hz.

3. The audio adapter according to claim 2 further comprising a second manually adjustable passive audio adjusting unit, wherein the second manually adjustable passive audio adjusting unit is connected between the first connector and the second connector by the signal line, and an audio adjustment range of the second manually adjustable passive audio adjusting unit is greater than or equal to 3000 Hz.

4. The audio adapter according to claim 1, wherein the first manually adjustable passive audio adjusting unit comprises:
a manually adjustable resistor;
a first capacitor, connected with the manually adjustable resistor in series; and
a second capacitor, connected with the manually adjustable resistor and the first capacitor in parallel.

5. The audio adapter according to claim 1, wherein an audio adjustment range of the first manually adjustable passive audio adjusting unit is greater than or equal to 3000 Hz.

6. The audio adapter according to claim 1, wherein the first manually adjustable passive audio adjusting unit comprises:
a manually adjustable resistor; and
a capacitor, connected with the manually adjustable resistor in series, wherein one of the manually adjustable resistor and the capacitor is grounded, and another one of the manually adjustable resistor and the capacitor is connected to the signal line.

7. An earphone, comprising:
a connector;
a first earphone unit;
a second earphone unit;
a first manually adjustable passive audio adjusting unit; and
a signal line, sequentially connected the connector, the first manually adjustable passive audio adjusting unit, and the first earphone unit and sequentially connected the connector, the first manually adjustable passive audio adjusting unit and the second earphone unit.

8. The earphone according to claim 7, wherein an audio adjustment range of the first manually adjustable passive audio adjusting unit is smaller than or equal to 300 Hz.

9. The earphone according to claim 8 further comprising a second manually adjustable passive audio adjusting unit, wherein the second manually adjustable passive audio adjusting unit is connected between the connector and the first earphone unit by the signal line, the second manually adjustable passive audio adjusting unit is also connected between the connector and the second earphone unit by the signal line, and an audio adjustment range of the second manually adjustable passive audio adjusting unit is greater than or equal to 3000 Hz.

10. The earphone according to claim 7, wherein the first manually adjustable passive audio adjusting unit comprises:
a manually adjustable resistor;
a first capacitor, connected with the manually adjustable resistor in series; and
a second capacitor, connected with the manually adjustable resistor and the first capacitor in parallel.

11. The earphone according to claim 7, wherein an audio adjustment range of the first manually adjustable passive audio adjusting unit is greater than or equal to 3000 Hz.

12. The earphone according to claim 7, wherein the first manually adjustable passive audio adjusting unit comprises:
a manually adjustable resistor; and
a capacitor, connected with the manually adjustable resistor in series, wherein one of the manually adjustable resistor and the capacitor is grounded, and another one of the manually adjustable resistor and the capacitor is connected to the signal line.

13. An earphone, comprising:
a connector;
a first earphone unit;
a second earphone unit;
a first manually adjustable passive audio adjusting unit;
a second manually adjustable passive audio adjusting unit; and
a signal line, sequentially connected the connector, the first manually adjustable passive audio adjusting unit, and the first earphone unit and sequentially connected the connector, the second manually adjustable passive audio adjusting unit, and the second earphone unit.

14. The earphone according to claim 13, wherein an audio adjustment range of the first manually adjustable passive audio adjusting unit is smaller than or equal to 300 Hz.

15. The earphone according to claim 14 further comprising a third manually adjustable passive audio adjusting unit, wherein the third manually adjustable passive audio adjusting unit is connected between the connector and the first earphone unit by the signal line, and an audio adjustment range of the third manually adjustable passive audio adjusting unit is greater than or equal to 3000 Hz.

16. The earphone according to claim 13, wherein the first manually adjustable passive audio adjusting unit comprises:
a manually adjustable resistor;
a first capacitor, connected with the manually adjustable resistor in series; and
a second capacitor, connected with the manually adjustable resistor and the first capacitor in parallel.

17. The earphone according to claim 13, wherein an audio adjustment range of the first manually adjustable passive audio adjusting unit is greater than or equal to 3000 Hz.

18. The earphone according to claim 13, wherein the first manually adjustable passive audio adjusting unit comprises:
a manually adjustable resistor; and
a capacitor, connected with the manually adjustable resistor in series, wherein one of the manually adjustable resistor and the capacitor is grounded, and another one of the manually adjustable resistor and the capacitor is connected to the signal line.

19. The earphone according to claim 13, wherein an audio adjustment range of the second manually adjustable passive audio adjusting unit is smaller than or equal to 300 Hz.

20. The earphone according to claim 19 further comprising a third manually adjustable passive audio adjusting unit, wherein the third manually adjustable passive audio adjusting unit is connected between the connector and the second earphone unit by the signal line, and an audio adjustment range of the third manually adjustable passive audio adjusting unit is greater than or equal to 3000 Hz.

21. The earphone according to claim 13, wherein the second manually adjustable passive audio adjusting unit comprises:
a manually adjustable resistor;
a first capacitor, connected with the manually adjustable resistor in series; and
a second capacitor, connected with the manually adjustable resistor and the first capacitor in parallel.

22. The earphone according to claim 13, wherein an audio adjustment range of the second manually adjustable passive audio adjusting unit is greater than or equal to 3000 Hz.

23. The earphone according to claim 13, wherein the second manually adjustable passive audio adjusting unit comprises:
a manually adjustable resistor; and
a capacitor, connected with the manually adjustable resistor in series, wherein one of the manually adjustable resistor and the capacitor is grounded, and another one of the manually adjustable resistor and the capacitor is connected to the signal line.

24. A speaker box, comprising:
a connector;
a speaker box body;
a first manually adjustable passive audio adjusting unit; and
a signal line, sequentially connected the connector, the first manually adjustable passive audio adjusting unit, and the speaker box body.

25. The speaker box according to claim 24, wherein an audio adjustment range of the first manually adjustable passive audio adjusting unit is smaller than or equal to 300 Hz.

26. The speaker box according to claim 25 further comprising a second manually adjustable passive audio adjusting unit, wherein the second manually adjustable passive audio adjusting unit is connected between the connector and the speaker box body by the signal line, and an audio adjustment range of the second manually adjustable passive audio adjusting unit is greater than or equal to 3000 Hz.

27. The speaker box according to claim 24, wherein the first manually adjustable passive audio adjusting unit comprises:
a manually adjustable resistor;
a first capacitor, connected with the manually adjustable resistor in series; and
a second capacitor, connected with the manually adjustable resistor and the first capacitor in parallel.

28. The speaker box according to claim 24, wherein an audio adjustment range of the first manually adjustable passive audio adjusting unit is greater than or equal to 3000 Hz.

29. The speaker box according to claim 24, wherein the first manually adjustable passive audio adjusting unit comprises:
a manually adjustable resistor; and
a capacitor, connected with the manually adjustable resistor in series, wherein one of the manually adjustable resistor and the capacitor is grounded, and another one of the manually adjustable resistor and the capacitor is connected to the signal line.
